(19) United States
(12) Patent Application Publication
(10) Pub. No.: US 2009/0127676 A1
(43) Pub. Date: May 21, 2009

(54) Back to Back Die Assembly For Semiconductor Devices

(76) Inventor: Jocel P. Gomez, Lapu-Lapu City (PH)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 11/941,322

(22) Filed: Nov. 16, 2007

(51) Int. Cl. H01L 23/495; H01L 21/60

(52) U.S. Cl. 257/666; 438/109; 257/E23.031; 257/E21.506

(57) ABSTRACT

Back to back die assemblies used in semiconductor devices and methods for making such devices are described. The die assemblies are made by stacking two dies together so that the back of one die (that does not contain any active electronic components) is attached to the back of another die. At the same time, though, the dies are electrically isolated from each other. This configuration provides a device with a small package size and a small land pattern. As well, a minimum number of metal traces are used in the semiconductor devices, leading to a very low on-resistance (R_{DS}) based on the size of the device footprint.

### FIELD

The application generally relates to integrated circuits (ICs) or semiconductor devices and methods for making such devices. More particularly, the application relates to back to back die assemblies used in semiconductor devices and methods for making such devices.

### BACKGROUND

Semiconductor processing builds hundreds of individual IC chips on a wafer. These individual chips are then cut, tested, assembled, and packaged for their various uses. The packaging step in this processing can be an important step in terms of costs and reliability. The individual IC chip must be connected properly to the external circuitry and packaged in a way that is convenient for use with that circuitry that is part of a larger electrical circuit or system (such as a printed circuit board or PCB).

To increase their performance, some semiconductor device packages (or semiconductor packages) have been developed that are highly integrated, i.e., with more electronic components incorporated into a given size. For example, some semiconductor packages have been made that contain multi-chip modules (or two IC chips in a single package). Packages comprising a multi-chip module can be formed by placing two (or more) semiconductor chips on a single chip carrier (such as a substrate or a lead frame). This method requires a larger surface area for the carrier in order to incorporate all the chips, thus making it difficult to reduce the size (or footprint) of the device. But as the chip carrier becomes larger, more thermal stress is generated between the packaged device and any external devices (such as the PCB). This increased stress can unfortunately allow delamination or peeling between the chip and the carrier, thereby creating reliability concerns.

Another way to create a multi-chip module is to stack the semiconductor chips vertically on the chip carrier. This method increases the overall height of the semiconductor package, but does not increase the footprint of the device. Thus, this method can prevent warpage and delamination, and thus is often used for making multi-chip modules.

Some of these stacked multi-chip modules have used wire bonding techniques to provide the necessary connection between the chip and the chip carrier (i.e., the leadframe). Other of the multi-chip modules, though, have used ball grid array (BGA) connections. In both types of devices, though, the amount of metal traces that are used in the devices results in an increased on-resistance (R_{DS}), which can lead to loss of power efficiency.

### SUMMARY

The application describes back to back die assemblies used in semiconductor devices and methods for making such devices. The die assemblies are made by stacking two dies together so that the back of one die (that does not contain any active electronic components) is attached to the back of another die. At the same time, though, the dies are electrically isolated from each other. This configuration provides a device with a small package size and a small land pattern. As well, a minimum number of metal traces are used in the semiconductor devices, leading to a very low on-resistance (R_{DS}) based on the size of the device footprint.

### BRIEF DESCRIPTION OF THE DRAWINGS

The following description of the semiconductor devices can be understood in light of FIGS. 1-28, in which:

FIG. 1 depicts a perspective view of an example of a semiconductor device containing a back-to-back die assembly;

FIG. 2 shows a side view of an example of a semiconductor device containing a back-to-back die assembly;

FIGS. 3A and 3B depict a top view of an example of a semiconductor device containing a back-to-back die assembly;

FIG. 4 shows exemplary parts of an example of a semiconductor device containing a back-to-back die assembly;

FIGS. 5A, B, and C depict top and side views of an example of a semiconductor device containing a back-to-back die assembly;

FIG. 6 depicts top and side views of an example of a semiconductor device containing a back-to-back die assembly;

FIG. 7 depicts several views of an example of a semiconductor device containing a back-to-back die assembly;

FIG. 8 depicts a perspective view of an example of a semiconductor device containing a back-to-back die assembly;

FIGS. 9 and 10 shows exemplary leadframes contained in an example of a semiconductor device containing a back-to-back die assembly;

FIG. 11 depicts three dimensional views of an example of a semiconductor device containing a back-to-back die assembly

FIG. 12 illustrates one method of making exemplary semiconductor device containing a back-to-back die assembly;

FIGS. 13-15 depict exemplary parts of a semiconductor device containing a back-to-back die assembly;

FIG. 16 depicts a perspective view of another example of a semiconductor device containing a back-to-back die assembly;

FIG. 17 shows several views of another example of a semiconductor device containing a back-to-back die assembly;

FIGS. 18A, B, C, and D depict a top view and side views of another examplary a semiconductor device containing a back-to-back die assembly;

FIGS. 19A and B show leadframes contained in another exemplary semiconductor device containing a back-to-back die assembly;

FIGS. 20 and 21 shows exemplary parts of a semiconductor device containing a back-to-back die assembly;

FIG. 22 depicts three dimensional views of another example of a semiconductor device containing a back-to-back die assembly;

FIGS. 23-24 illustrates methods of making a semiconductor device containing a back-to-back die assembly;

FIGS. 25-27 shows the uses of another example of a semiconductor device containing a back-to-back die assembly; and

FIG. 28 depicts exemplary parts of a semiconductor device containing a back-to-back die assembly.

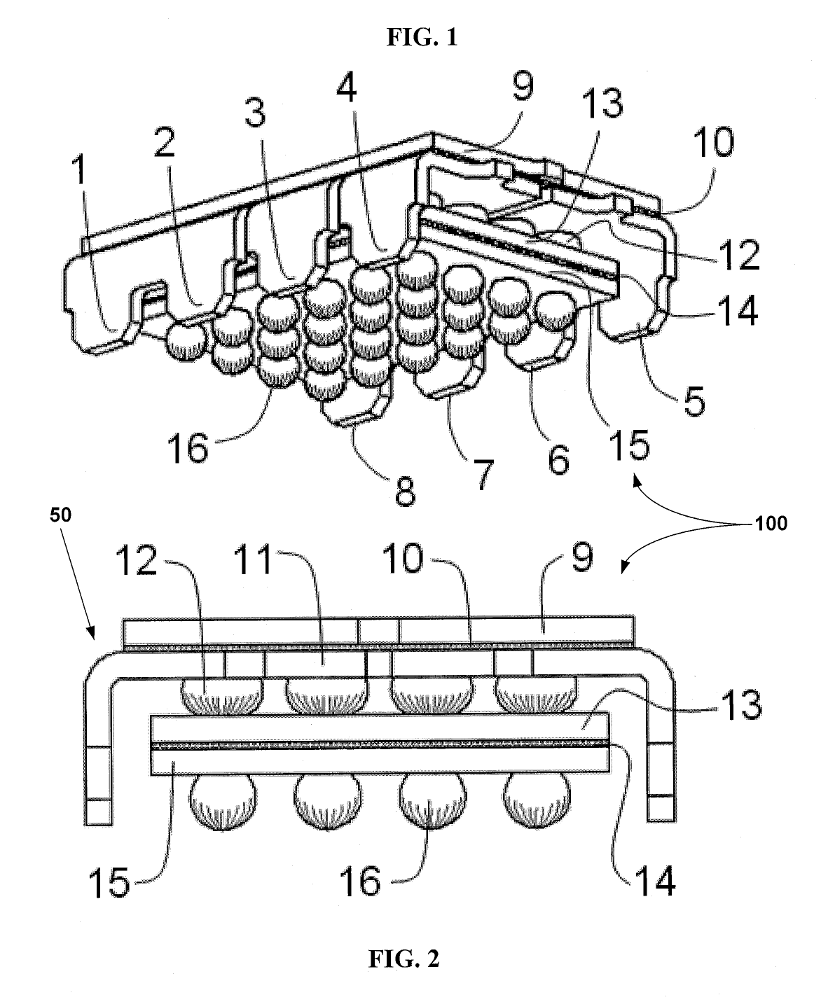

FIGS. 1-28 illustrate specific aspects of the semiconductor devices and associated methods of making and using such devices. Together with the following description, the Figures demonstrate and explain the principles of the semiconductor devices and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such devices can be implemented and used without employing these specific details. For example, while the description focuses on semiconductor devices, it can be modified to be used in other electrical devices that are packaged in a similar manner as semiconductor devices.

One example of the semiconductor devices that contain packaging (or semiconductor packages) is shown in FIGS. 1-15. In these Figures, the semiconductor package 100 contains an upper die 13 and a lower die 15. Each semiconductor die 13 and 15 in the semiconductor package 100 can contain an electrical component, such as a transistor like a MOSFET or a BJT (bipolar junction transistor), diode, or other type of electrical device. In some embodiments, the upper and lower dies 13 and 15 may comprise of vertical MOSFET with a trenched gate. An expanded view of the various components in the package 100 is illustrated in FIG. 8.

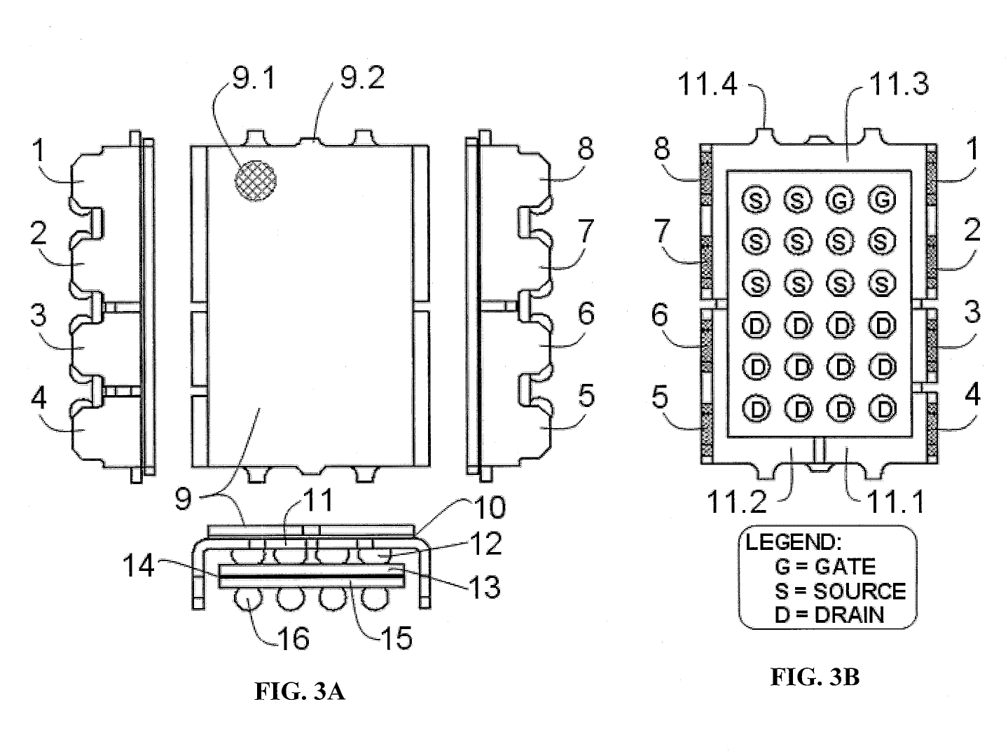

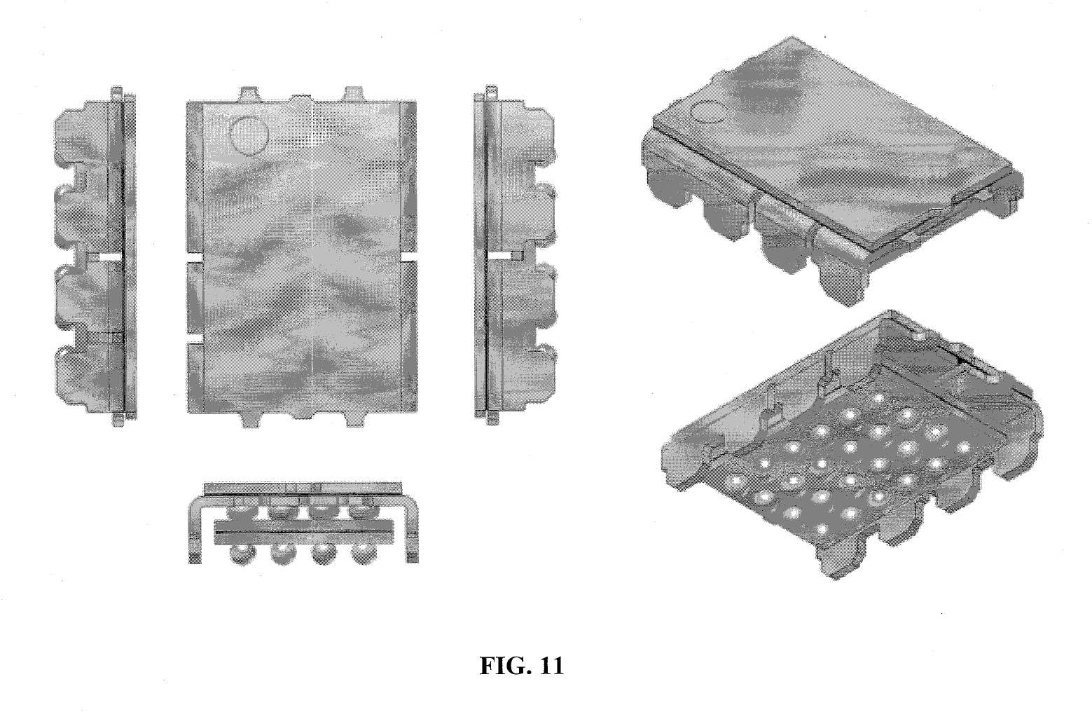

As shown in FIGS. 1-2, 9, and the 3D view of FIG. 11, the semiconductor package 100 also contains a support structure 9. As implied by its name, the support structure 9 provides support to the remainder of the package 100. Any known support mechanism can be used as the support structure 9. In some embodiments, though, the support structure 9 is made of a conductive material, like a metal or metal alloy, that has a substantially rectangular shape. Of course, the support structure could have any shape that provided the desired support to the semiconductor package 100. As shown in FIG. 3, the support structure 9 can contain an indicator 9.1 (i.e., a pin 1 indicator) to show the desired location of a part of the electronic component(s) in the device (i.e., the gate in the lower die 15). The support structure 9 can also contains a tie bar 9.2 which is used to connect the support structure 9 to the rest of the device 100.

The semiconductor package 100 also contains a layer 10. The layer 10 serves to attach and electrically insulate the support structure 9 to the rest of the package 100 and, in particular to the leadframe 50. Accordingly, layer 10 can comprise of any material that will serve both of these functions, such as a high thermal-resistant, double-sided adhesive thin tape or film. In some embodiments, the layer 10 may the same material as support frame so that the support material frame is also non-conductive. In other embodiments, the support structure 9 and layer 10 can comprise a single, homogeneous non-electrically conductive (plastic, ceramic, pre-molded, or laminated) material capable of supporting the package assembly.

When the layer 10 is a thin material, it can be pre-attached to the support frame 9 and connected to a leadframe structure (or leadframe) 50 with by a clamping and thermal curing process. The leadframe 50 is formed so that it is relatively planar in the area of the support structure 9 but then bends and extends substantially perpendicular to that planar area. The leadframe 50 supports the back-to-back die assembly containing the upper and lower dies, serves as part of the I/O interconnection system, and also provides a thermally conductive path for dissipating the majority of the heat generated by the dies. As known in the art, the leadframe 50 may be any one of many leadframe structures in a leadframe carrier, which can be in the form of a strip, or a reel.

The leadframe 50 generally contains two portions. The first portion comprises an interconnected metallized pattern containing a die attach region (or die attach pad 11) to which the die assembly is attached. To enhance the bond between the die assembly and the leadframe structure 50, the die attached pad 11 surface may be formed with defined surface roughness or may have defined metallic plated layer so that the material solder bumps 12 tightly adheres thereto and will have reliable solder joints. As shown in FIG. 3B, the attach pad can contain several regions, i.e., a bump attach pad 11.1 that will be connected to the gate of the electronic component in the upper die, a bump attach pad 11.2 that will be connected to the source of the electronic component in the upper die, a bump attach pad 11.3 that will be connected to the drain of the electronic component in the upper die, and a tie bar 11.4. Again, the tie bar 11.4 serves as a connection between the leadframe 50 and the remainder of the device.

The second portion of the leadframe structure 50 contains several leads that end in terminal regions (or terminals). The individual leads extend away from the die attach pad 11. As shown in FIGS. 1 and 3A, the terminals of the leadframe 50 comprise drain terminals (1, 2, 7, and 8), source terminals (3, 5, and 6), and a gate terminal 4. The terminals serve as the electrical connection between the electronic components in the upper die 13 and the circuitry in the external device (i.e., the PCB).

The material of the leadframe 50 may comprise any metal, such as copper or a copper alloy. In some instances, the leadframe 50 can contain a layer of metal plating (not shown), if desired. The layer of metal plating may comprise NiPdAu or may comprise an adhesion sublayer, a conductive sublayer, and/or an oxidation resistant layer. For example, the leadframe structure 50 may include a leadframe plating containing an adhesion sublayer and a wettable/protective sublayer.

The die attach pad 11 of the leadframe 50 is connected to the upper die 13 by multiple solder bumps 12, often arranged in an array. The array of solder bumps 12 is contained between the upper die 13 and the leadframe 50 in those locations where electrical connections are needed between the electronic component(s) in the upper die 13 and the leadframe 50. Any known solder material can be used for the solder bumps, including SnPbAg, PbSn, SnSb, Pb free, electroless NiAu, Cu bumps, and a combination of Cu bumps surrounded with a solder ball.

As best depicted in FIGS. 1 and 2, the semiconductor package 100 contains a die assembly of an upper die 13 and a lower die 15. These two dies are arranged in a back-to-back relationship in the sense that the inactive surfaces (containing no active electronic component) of the dies face each other and the active surfaces of the die are exposed (and available to be connected to solder bumps 12 and 16). The dies 13 and 15 are attached to each other by attach layer 14. The attach layer 14 is not electrically conductive so that each die is electrically isolated from the other. Thus, the attach layer 14 comprises any non-conductive materials that are also an adhesive. Examples of such materials include epoxy-based materials and high thermal-resistant thermal adhesive films or tapes.

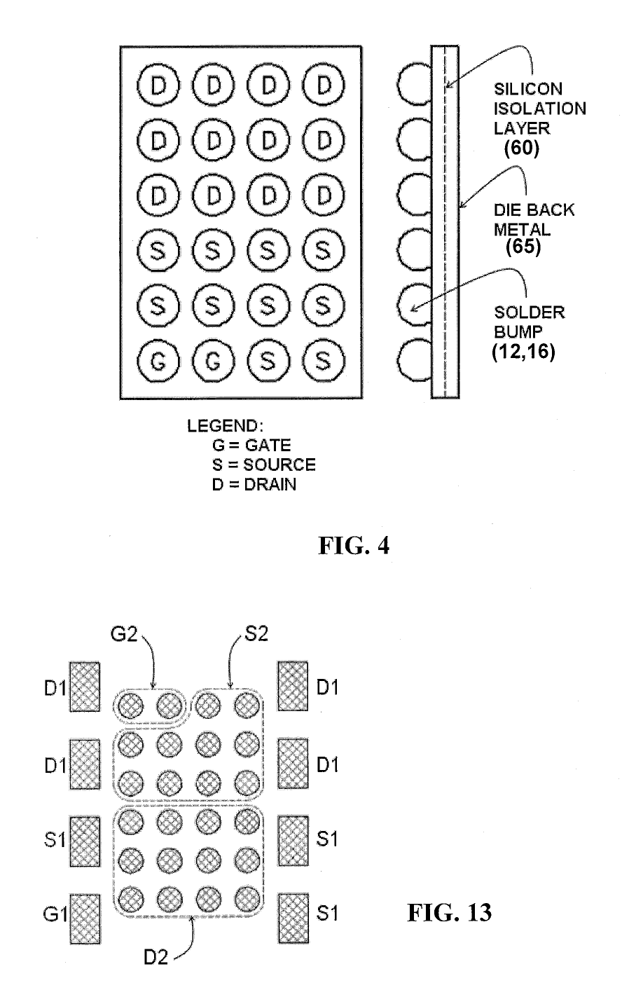

Both the lower and upper dies contain, as shown in FIG. 4, an isolation layer 60 located within the die itself. The isolation layer 60 can be made of any isolating material, including a silicon oxide isolation layer. Both the lower and upper dies also contain an active layer where the bumps are connected, and an isolated die back layer 65. The die back surface layer 65 can be made with a defined metal plated area that will provide reliable adhesion to the adhesive layer 14. The respective solder bumps 12 and 16 are all pre-attached to the die active surface so that the solder bumps 12 and 16 are attached to the die during the wafer level processing.

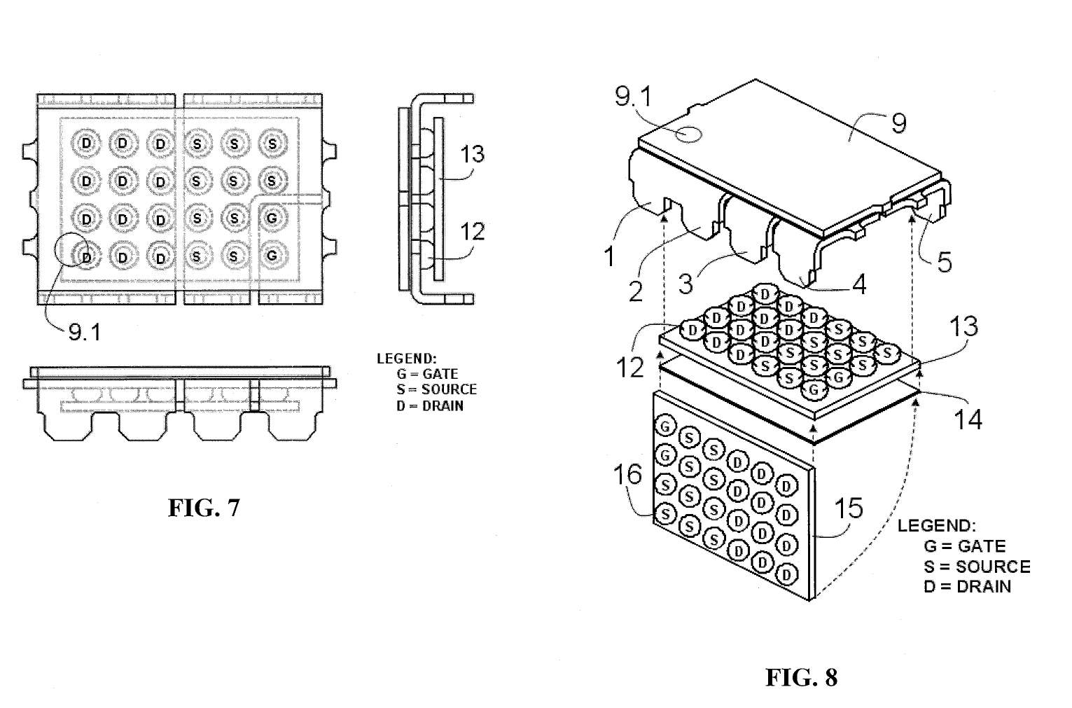

The upper die 13 contains any known electronic component (not shown) on its active surface. Each part of the electronic component (i.e., source, drain, and gate as shown in FIG. 7) to which the leadframe 50 will be connected can contain an optional bond pad (not shown) on its upper surface. The bond pad operates to help bond the respective solder bump connect to the upper die while also protecting the electronic component.

The upper die 13 contains the drain, source, and gate regions of the exemplary transistor that serves as the electronic component, as shown in FIGS. 3, 7, and 8. The location of the drain regions are shown by the letter D, the location of the source regions are shown by the letter S, and the location of the gate regions are shown by the letter G. In some embodiments, these regions are the source, drain, and gate of a MOSFET device(s).

The lower die 15 contains an electronic component (not shown) on its active surface. These electronic components will be connected directly to the circuitry of the external device (i.e., a PCB) through solder bumps 16. Each part of the electronic component (i.e., source, drain, and gate) to which the circuitry of the external device will be connected can contain an optional bond pad (not shown) on its surface. The bond pad operates to help bond the respective solder bump to the upper die while also protecting the electronic component.

The lower die 15 also contains the drain, source, and gate regions of the electronic component, as shown in FIG. 4 and 8. The location of the drain regions are shown by the letter D, the location of the source regions are shown by the letter S, and the location of the gate regions are shown by the letter G. In some embodiments, these regions are the source, drain, and gate of a MOSFET device(s) contained in the lower die 15.

The solder bumps 12 and 16 should be configured to minimize the height of the semiconductor package 100. Accordingly, the height of solder bumps 12 and 16, the die thickness, and the leadframe thickness can be configured in order to have any desired thickness, including a thinner semiconductor package 100. The solder bumps can comprise any solder material known in the art, whether that material is Pb free or contains Pb.

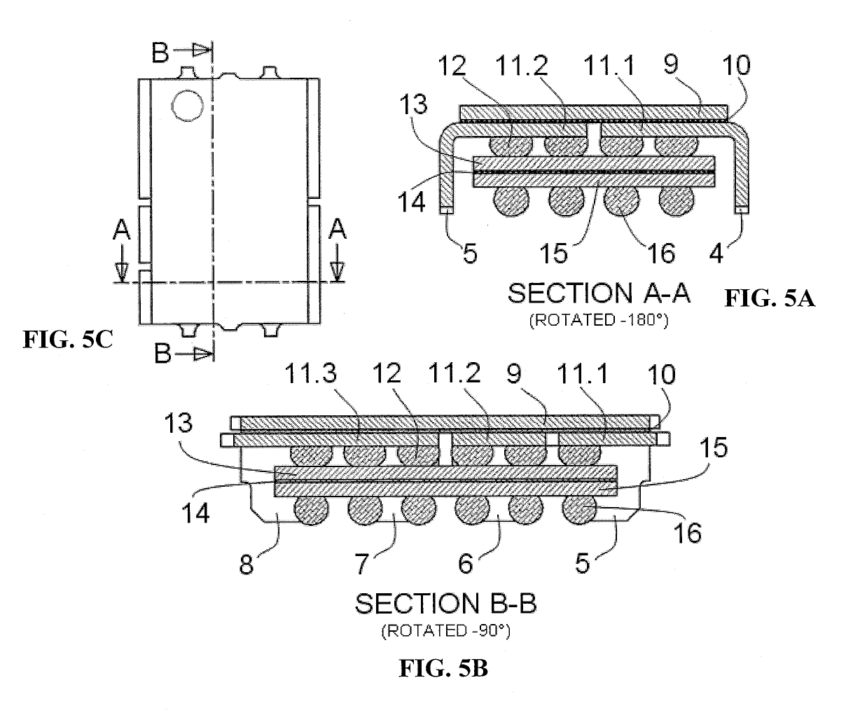

Two additional side views of the semiconductor package 100 are illustrated in FIGS. 5A, B, and C. The top view of the device 100, which is similar to that view shown in FIG. 3, is shown in FIG. 5C and has been designated with cross-sections A-A and B-B. The view along cross-section A-A is depicted in FIG. 5A and the view along cross-section B-B is depicted in FIG. 5B. As shown in FIG. 5A, the gate and source regions of the die attach pad are not electrically connected to each other. FIG. 5A also illustrates the respective locations of the terminals 4 and 5 relative to the rest of the remainder of the leadframe 50. And as shown in FIG. 5B, the source and drain attach pads are also not electrically connected to each. FIG. 5B also illustrates the respective locations of the terminals 5, 6, 7, and 8 relative to the rest of the remainder of the leadframe 50

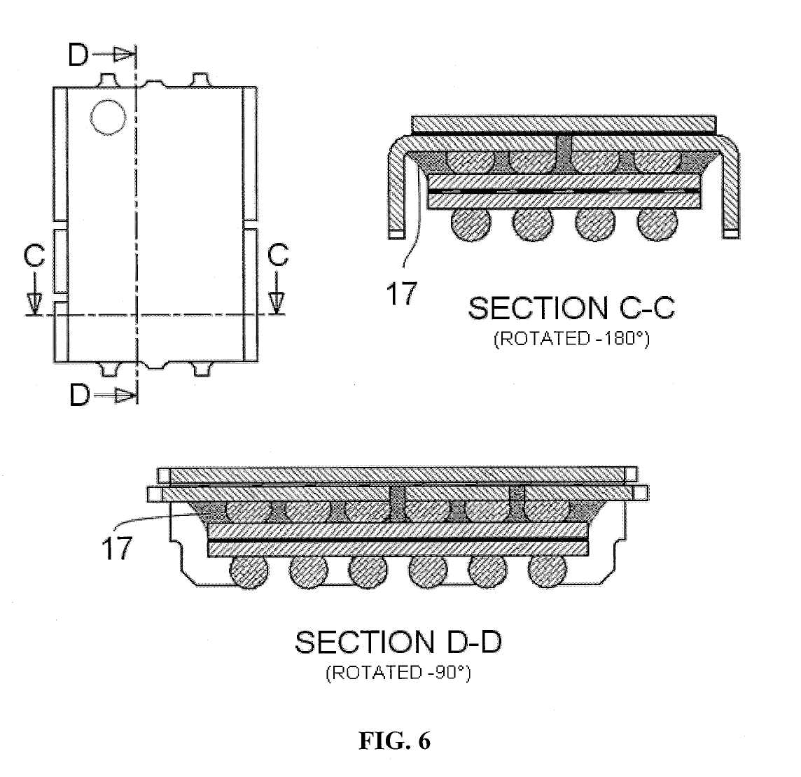

In some embodiments, the semiconductor package 100 can contain a molding material 17 that partially encapsulates the device. These embodiments are shown in FIG. 6, where the molding material 17 fills in the areas between the support structure 9, the leadframe 50, and the upper die 13. In these embodiments, the molding material 17 therefore serves as an underfill material, which provides the advantage of providing adhesion between the active surfaces of die 13 to the die attach pad 11 and protection of solder joints of solder bumps 12.

The molding material 17 used in these embodiments can comprise any molding material known in the art that flows well and therefore minimizes the formation of any gaps. In some aspects, the molding material comprise an epoxy molding compound such as an epoxy material with a low thermal expansion (a low CTE), fine filler size (for good flow distribution of the molding material), and high adhesion strength.

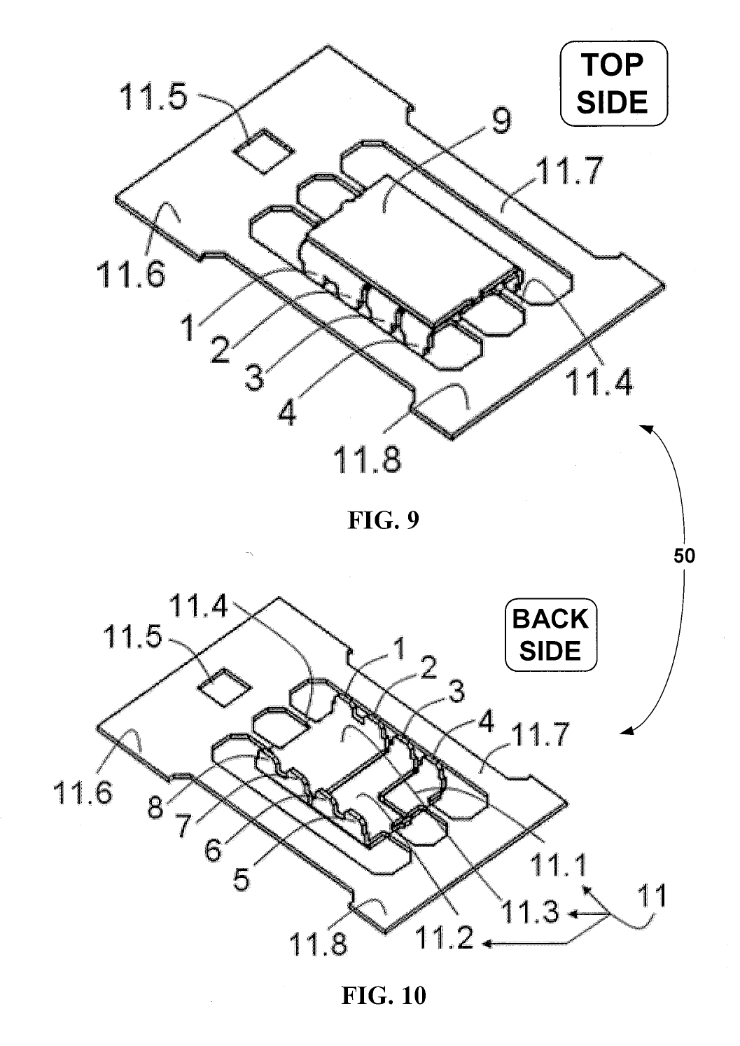

An expanded view of the leadframe 50 is depicted in FIGS. 9 and 10. In the top view shown in FIG. 9, the top side of the support structure 9 rests over the die attach region of the leadframe 50. Besides the gate, source, and drain attach regions (11.1, 11.2, and 11.3) of the die attach pad, the leadframe 50 also contains a tie bar 11.4, an index hole 11.5 that is used in aligning the components together during the assembly process. The leadframe 50 also contains an upper horizontal support 11.6, a vertical support 11.7, and a lower horizontal support 11.8. A view of back side the leadframe 50 is shown in FIG. 10.

The semiconductor packages 100 described above can be made using any suitable method that forms the structures illustrated. In some embodiments, the dies for the upper and lower dies are first provided with the isolation layer 60. Isolation layer 60 can be provided at wafer level manufacturing, including the die back 65 surface plating. Then, the various electronic components (i.e., the transistors) are manufactured, an array of bonding pads then provided, solder bumped, cut, tested, and die-bonded to a substrate as known in the art to form a the upper die 13 and the lower die 15 containing the electronic components.

Next, the leadframe 50 (as shown in FIGS. 9 and 10) is formed by any known method, for example, metal stamping and etching processes. If desired, a layer of metal plating may be formed on the base metal used in the leadframe by processes such as electroless plating, sputtering, or electroplating. A pre-plated leadframe can also be used instead.

The lead frame 50 and the support structure 9 are then attached by applying the attach layer 10 to one—or both—of their surfaces and then pressing them together until the material of the attach layer 10 has cured. Then, the solder bumps 12 are then provided in the desired locations of the upper die 13, i.e., those where the bond pads are located or over where the source, drain, and gate regions of the MOSFET are located. The solder bumps 12 can be provided using any mechanism known in the art. In some instances, the solder bumps 12 can be instead provided on the die attach pad of the leadframe 50 as known in the art. The solder bumps 16 can similarly be provided in the desired locations of the lower die 15 during the same process or in a different process, or the solder bumps can be attached to the die active area during wafer level manufacturing.

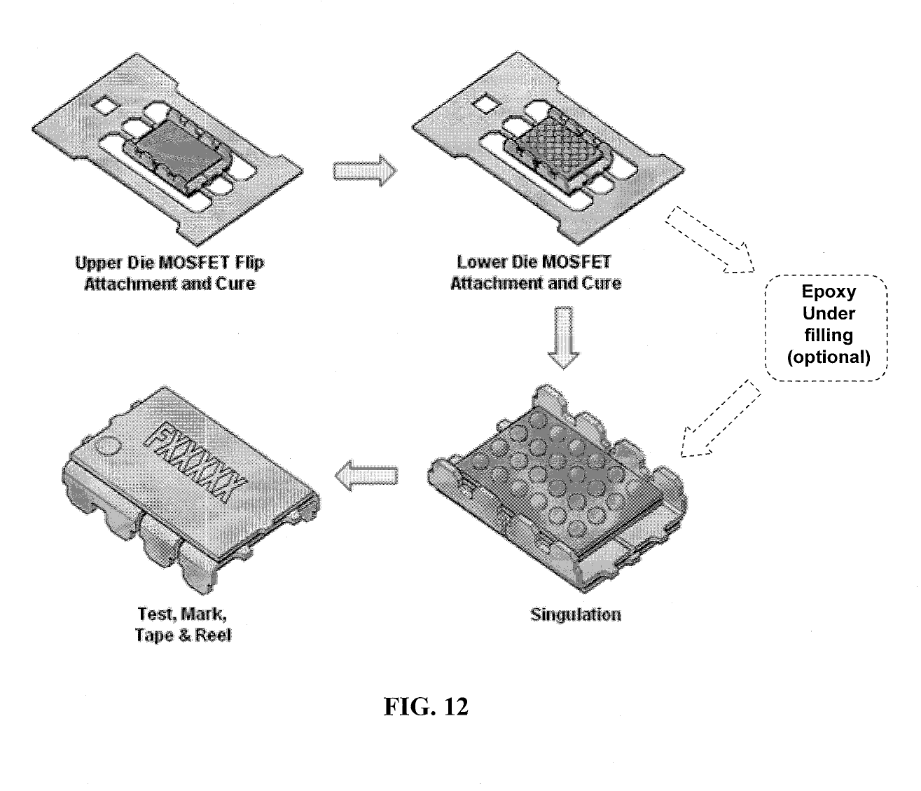

Next, the upper die 13 is then flip-attached to the die attach pad of the leadframe 50 as shown in FIG. 12. In this process, the solder bumps 12 become attached to the leadframe and thereby attach the upper die to the structure of the lead frame 50. In some embodiments, the leadframe 50 and the upper die 13 are joined using any suitable flipchip process. In this process, the upper die 13 is flipped over to the die attach pad 11 of leadframe 50 while the structure is heated in a defined temperature reflow profile. During the heating process, the solder bumps 12 will melt to form solder joints and a die position stand-off will be established when the resulting structure is cooled down.

Next, the lower die 15 (already containing the bumps 16) is attached to the back surface 65 of the upper die 13. In this process, the layer 14 is provided on the back surface of die 13 and then the die 15 is attached and cured at a temperature lower than the temperature used during attachment of die 13 so the solder bumps 12 will not re-melt. In some embodiments, the die 13 attachment process can use a temperature of about 310° C. and the epoxy layer curing process can use a temperature of 250° C. In some embodiments, the layer 6 may be in a form of thin adhesive material that can be pre-attached to the back surface of die 15. Once cured, the lower and upper dies are attached to each other, with the solder bumps 16 on the lower die 15 exposed. In some embodiments, the solder bumps 16 need not be formed on the lower die before the attachment, but can be formed on the lower die 15 after it has been attached to the upper die 13.

At this stage, if the semiconductor package 100 contains an epoxy under fill material, it is then provided. In the embodiments where only a partial encapsulation is present, the material (i.e., epoxy) for the molding is coated onto the die assembly and lead frame and then cured so that resulting layer 17 is formed (as shown in FIG. 6).

Once these processes are performed, the devices are singulated as known in the art. Then, the singulated semiconductor packages may be electrically tested. After electrical testing, the top surface of frame support 9 in the semiconductor packages may be laser marked according to the device code and index marked for orientation indication of the gate of die 16. Finally, the devices may be taped and reeled as known in the art.

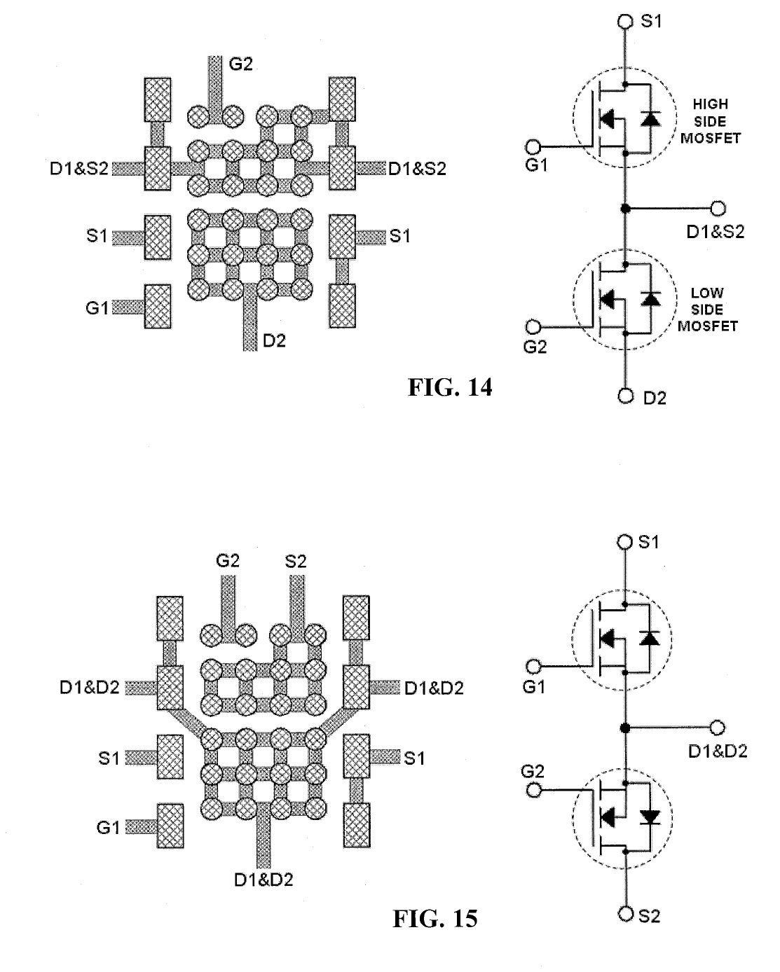

The devices described above have several advantages. First, as shown in FIG. 13, these devices have a low amount of metal traces that connect the electronic component (i.e., MOSFET) in the upper die to the terminals of the leadframe 50. These devices also allow the electronic component in the lower die to be directly connected to the PCB via the solder bumps 16 without using a leadframe. Thus, the devices have a low R_{DS}.

Another advantage comprises the size of the land pattern and the overall package. The devices described above have a compact dual die configuration by stacking the dies in a back to back configuration. Other devices with a dual-die configuration usually fold, rather than stack, the dies together. With the back to back stacked-die configuration, the devices use a smaller land pattern area and therefore have a smaller package size.

Yet another advantage of the devices described above relates to the flexibility of the end uses of the devices. The devices have a stacked back-to-back die configuration while allowing the dies to still be electrically isolated from each other. This allows a wide ranges of uses for the devices, including being used as a common drain-source interconnection in scan driver block, inverter blocks, and any other application or end-use that requires half-bridge connection configuration, as shown in FIG. 14, and in scan switch blocks (i.e., DC/DC switching devices), as shown in FIG. 15.

Another advantage of the devices described above relate to the location of the bumps. As described above, the gate, source and drain bumps for each of the upper and lower dies are located on one side of the die. Such configuration allows simplicity for all of the electrical connections towards the gate, source and drain. And unlike conventional dies, the functional drain terminal is provided at the back side of the die.

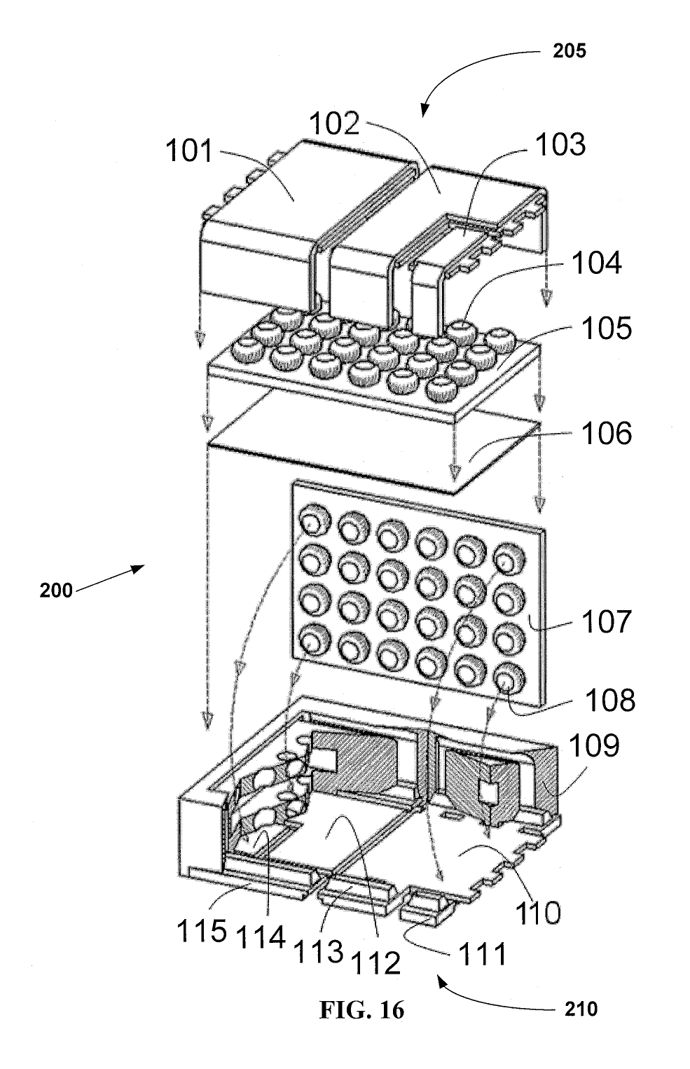

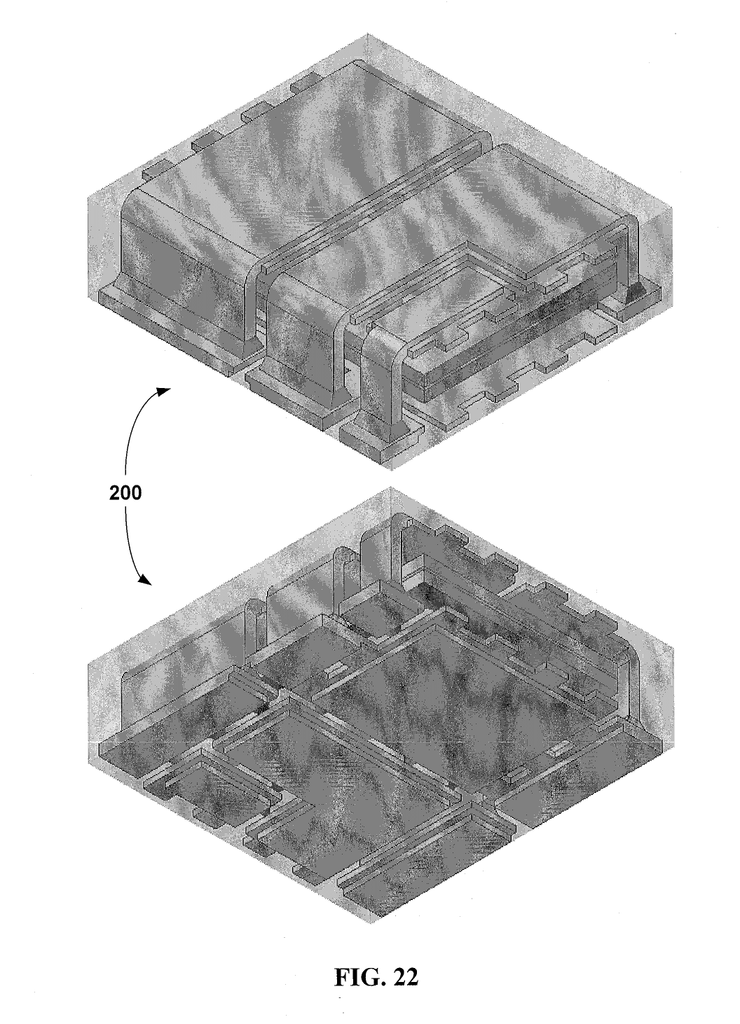

Another example of the semiconductor devices or semiconductor packages is shown in FIGS. 16-28. As shown in FIG. 16 and the 3D view in FIG. 22, the semiconductor package 200 contains an upper die 105 and a lower die 107. As noted above, each semiconductor die in the semiconductor package 200 can contain an electrical component, such as a transistor like a MOSFET or a BJT (bipolar junction transistor), diode, or other type of electrical device.

The semiconductor package 200 contains a leadframe structure (or leadframe) 205 The leadframe 205 is formed so that it is relatively planar in the area of the dies, but then bends and extends substantially perpendicular to that planar area. The leadframe 205 supports the back-to-back die assembly and also provides a thermally conductive path for dissipating the majority of the heat generated by the dies. As known in the art, the leadframe 205 may be one of many leadframe structures in a leadframe carrier, which can be in the form of a strip. During processing, the leadframe structures may be present in a leadframe carrier if multiple leadframe structures are processed together.

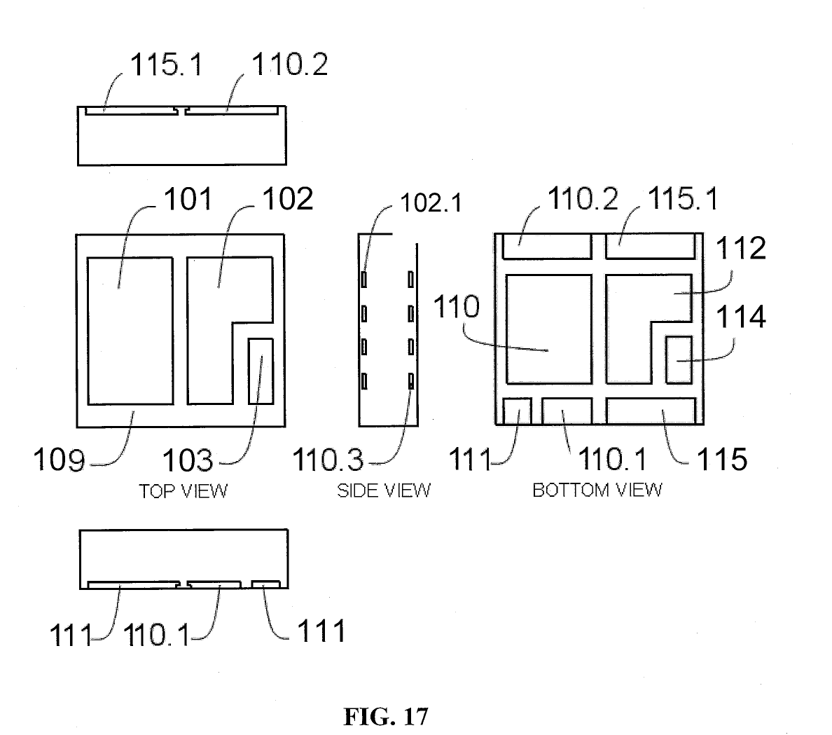

The leadframe 205 contains a die attach pad region to which the die assembly (of upper die 105 and lower die 107) is attached. The leadframe 205 also contains a gate contact pedestal 103 that will be connected to the gate of the electronic component in the upper die 105, a source contact pedestal 102 that will be connected to the source of the electronic component in the upper die 105, and a drain contact pedestal 101 that will be connected to the drain of the electronic component in the upper die. As well, the leadframe 205 contains a tie bar 102.1, as depicted in FIG. 17.

The leadframe 205 also contains several bent leads which extend from the die attach pad region and end in terminal regions of leadframe 210 (or terminals). The terminals of the leadframe 205 comprise drain terminal that is to be connected to lead terminals 115 and 115.1 of leadframe 210, source terminal is to be connected to the frame surfaces 110.1 & 110.2 of leadframe 210, and a gate is to be connected to the terminal pad surface of 111 of leadframe 210. The terminals serve as a connection between the lead frame 210 and the circuitry in the external device (the PCB) to which the semiconductor package 200 is connected.

The leadframe 205 is connected to the upper die 105 by solder bumps 104. The array of solder bumps 104 is contained between the upper die 105 and the leadframe 205 in those locations where electrical connections are needed. Any known solder material can be used for the solder bumps 104, including SnPbAg, PbSn, SnSb, Pb free, electroless NiAu, Cu bumps, and a combination of a Cu bump surrounded by a solder ball.

As depicted in FIGS. 16, 18, and 22, the semiconductor package 200 contains a die assembly of an upper die 105 and a lower die 107. These two dies are arranged in a back-to-back relationship in the sense that the inactive regions of the dies face each other and the active regions of the die are exposed (where solder bumps 104 and 108 are connected). The dies 105 and 107 are attached to each other by die attach material layer 106. The attach layer 106 is not electrically conductive so that each die is electrically isolated from the other. Thus, the attach layer 106 comprises any non-conductive material that is also an adhesive, such as an epoxy-based material.

Both the lower and upper dies contain, as shown in FIG. 4, an isolation layer 60. The isolation layer 60 can be made of any isolating material, including a silicon oxide isolation layer. Both the lower and upper dies also contain an active layer where the bumps are connected, and an isolated die back layer 65. The die back surface layer 65 can be made with a defined metal plated area that will provide reliable adhesion to the adhesive layer 106. The respective solder bumps 104 and 108 are all pre-attached to the die active surface so that the solder bumps 104 and 108 are attached to the die during the wafer level processing.

The upper die 105 contains an electronic component (not shown) on its active surface. Each part of the electronic component to which the leadframe 205 will be connected can contain an optional bond pad (not shown) on its upper surface. The bond pad operates to help bond the respective solder bump to the upper die while also protecting the electronic component.

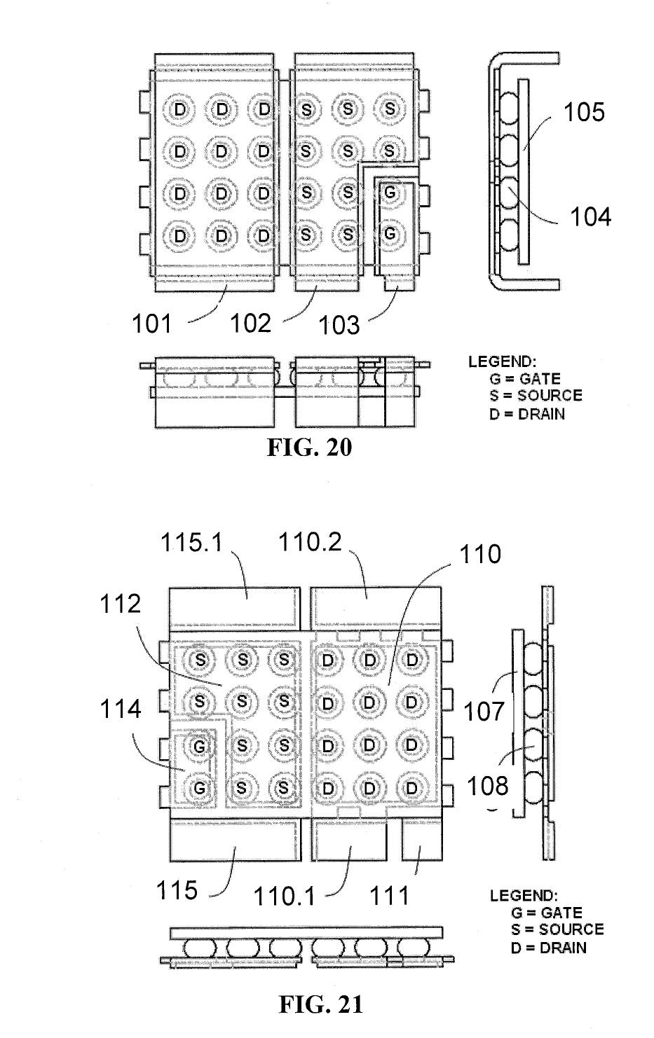

The upper die 105 also contains the drain, source, and gate regions of the electronic component, as shown in FIG. 20. The location of the drain regions are shown by the letter D, the location of the source regions are shown by the letter S, and the location of the gate regions are shown by the letter G. In some embodiments, these regions are the source, drain, and gate of a MOSFET device(s) as illustrated in FIG. 20.

The lower die 107 also contains an electronic component (not shown) on its active surface. These electronic components will be connected to another leadframe 110 (or lower leadframe) through solder bumps 108. Each part of the electronic component to which the sold bumps will be connected can contain an optional bond pad (not shown) on its surface. The bond pad operates to help bond the respective solder ball to the upper die while also protecting the electronic component.

The lower die 107 also contains the drain, source, and gate regions of the electronic component, as shown in FIG. 21. The location of the drain regions are shown by the letter D, the location of the source regions are shown by the letter S, and the location of the gate regions are shown by the letter G. In some embodiments, these regions are the source, drain, and gate of a MOSFET device(s) contained in the lower die 107 as shown in FIG. 21.

The lower die 107 contains an array of solder bumps 108 that is contained between the lower die 107 and another leadframe 210 in those locations where electrical connections are needed. Any known solder material can be used for the solder bumps, including any of those mentioned above.

As known in the art, the leadframe 210 may be one of many leadframe structures in a leadframe carrier, which can be in the form of a strip. During processing, the leadframe structures may be present in a leadframe carrier if multiple leadframe structures are processed together. The leadframe 210 contains a die attach pad region or contact pedestals where the bumps 108 of lower die 107 will be attached. The leadframe 210 contains a gate contact pedestal 114 that will be connected to the gate of the electronic component in the lower die, a source contact pedestal 112 that will be connected to the source of the electronic component in the lower die, and a drain contact pedestal 110 that will be connected to the drain of the electronic component in the lower die. The leadframe 210 also contains tie bar 110.3.

The material of the leadframes 205 and 210 may comprise any metal, such as copper or a copper alloy. In some aspects, they can contain a layer of metal plating (not shown), if desired. The layer of metal plating may comprise an adhesion sublayer, a conductive sublayer, and/or an oxidation resistant layer. For example, the leadframe 205 and/or 210 may include a leadframe plating containing NiPdAu or an adhesion sublayer and a wettable/protective sublayer.

The solder bumps 104 and 108 should be configured to minimize the height of the semiconductor package 200. Accordingly, the height of solder bumps 12 and 16, the die thickness, and the leadframe thickness can be configured in order to have any desired thickness, including a thinner semiconductor package 100. The solder bumps can comprise any solder material known in the art, whether that material is Pb free or contains Pb.

The semiconductor package 200 can be encapsulated with any known mold compound. The mold compound 109 in FIG. 16 has been partially removed so that the rest of the semiconductor package 200 can be illustrated. The molding material of mold compound 109 mostly or completely encapsulates device. These embodiments are shown in FIGS. 17 and 22, where the molding material 109 is shown to encapsulate the device except for the uppermost and lowermost surfaces of the package 200.

The molding material used in these embodiments can comprise any molding material known in the art that flows well and therefore minimizes the formation of any gaps. In some aspects, the molding material comprise an epoxy molding compound such as an epoxy material with a low thermal expansion (a low CTE), fine filler size (for good flow distribution of the molding material), and high adhesion strength.

Several external views of the semiconductor package 200 are illustrated in FIG. 17. As shown in this Figure, the semiconductor package 200 contains a tie bar 102.1 for the leadframe 205 and a tie bar 110.3 for the leadframe 210. This Figure also illustrates other components that can be viewed externally, including the drain terminals for the lower die 110.1 and 110.2, as well as the drain terminal 115.1 for the upper die.

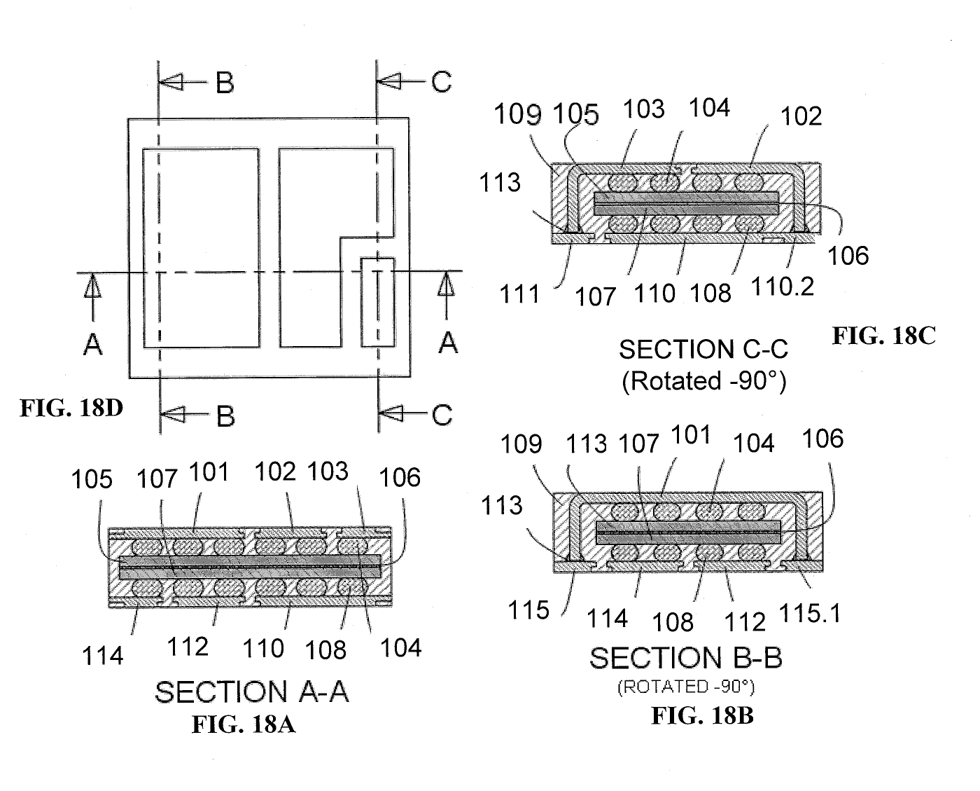

Additional views of the semiconductor package 200 are illustrated in FIG. 18. The top view of the semiconductor package 200 is shown in FIG. 18D and has been designated with cross-sections A-A, B-B, and C-C. The view along cross-section A-A is depicted in FIG. 18A, the view along cross-section B-B is depicted in FIG. 18B, and the view along cross-section C-C is depicted in FIG. 18C. Collectively, these Figures illustrate the various electrical connections among between the dies and the leadframes to which they are respectively attached.

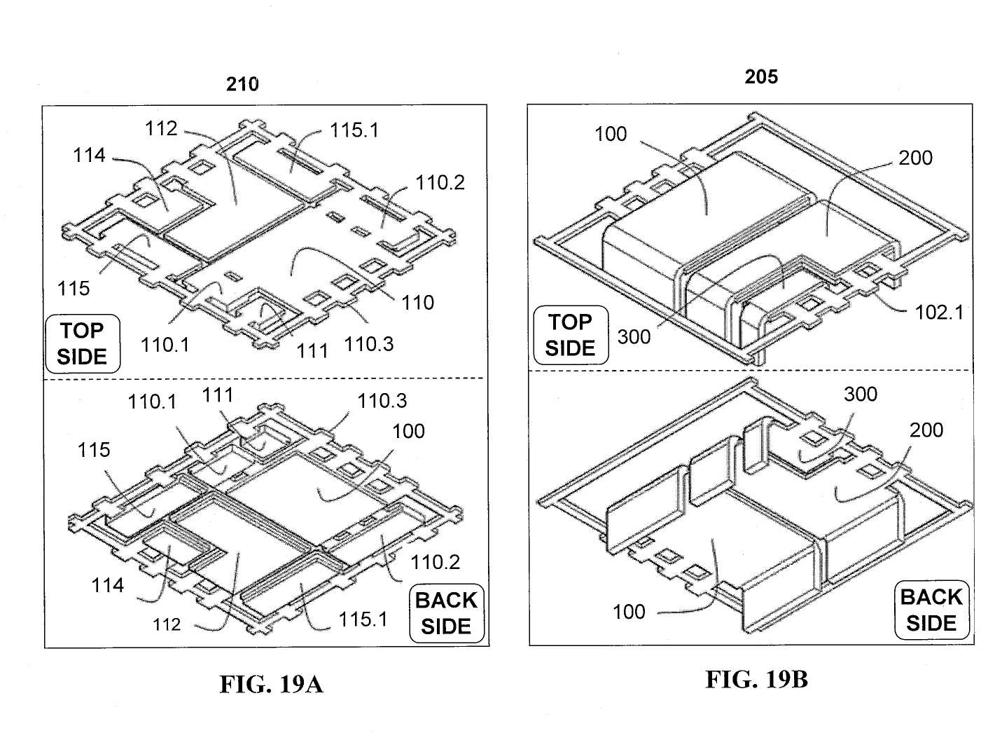

An expanded view of the lead frame structures 205 and 210 are depicted in FIGS. 19A and 19B. The leadframe 205 is shown in FIG. 19B, with both a top view and a bottom view. The leadframe 210 is shown in FIG. 19A, with both a top view and a bottom view. As can be seen in these Figures, each of the leadframes contains the contact pedestals for the source, drain, and gate regions of the adjacent die. As well, further details of the entire structure of the leadframes 205 and 210 are shown in FIGS. 19A and B.

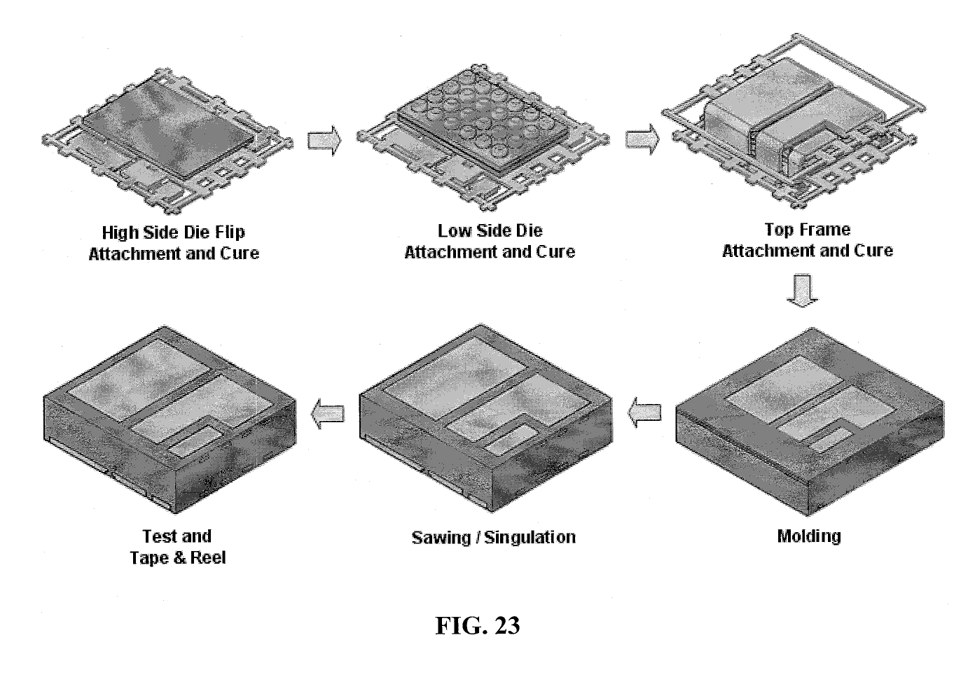

The semiconductor package 200 can be made using any suitable method that forms the structures illustrated and described above. In some embodiments, the method illustrated in FIG. 23 is used. In these embodiments, the dies for the upper and lower dies are provided with the isolation layer 60 in order to have an isolated die back surface 65. Then, the various electronic components (i.e., the MOSFETs) are manufactured on the active surface, an array of bonding pads then provided, solder bumped, cut, tested, and die-bonded to a substrate as known in the art to form the upper die 105 and the lower die 107 containing the electrical components as depicted in FIG. 4.

Next, the leadframes 205 and 210 (as shown in FIG. 19) are formed by any known method, for example, any metal stamping and/or etching processes. If desired, a layer of metal plating may be formed on the base metal used in the lead frame by processes such as electroless plating, sputtering, or electroplating. A pre-plated leadframe can also be used instead. These two leadframes 205 and 210 can be formed in the same procedure or in different procedures.

Then, the solder bumps 104 and 108 are then provided in the desired locations of the upper die 105 and the lower die 107. The solder bumps 104 and 108 can be provided using any mechanism known in the art. The solder bumps can be provided in the desired locations of the lower die 107 and the upper die 105 during the same process or in a different process.

Next, the lower die 107 is attached to the lower leadframe 210. In this process, the solder bumps 108 become attached to the lead frame 210 and bond the lower die 107 to the leadframe 210. In some embodiments, the lead frame 210 and the lower die can be joined using any suitable flipchip process. In this process, the lower die 107 is flipped over and aligned with the leadframe 210 while the structure is heated in a defined temperature reflow profile. During the heating process, the solder bumps 108 will melt to form solder joints and a die position stand-off will be established when the resulting structure is cooled down.

Next, the upper die 105 (containing solder balls 104) is attached to the back surface 65 of the lower die 107. In this process, die attach epoxy layer 106 is provided on the back surface of die 107 and then die 105 is attached and cured at a temperature relatively lower than the temperature used during attachment of die 107. In some embodiments, the layer 106 may be in a form of thin adhesive material that can be pre-attached to the back surface of die 105. Once cured, the lower and upper dies are attached to each other, with the solder bumps 104 on the upper die 105 exposed. In some embodiments, the solder bumps 104 need not be formed on the upper die before the attachment, but can be formed on the upper die 105 after it has been attached to the lower die 107.

Then, the leadframe 205 is attached to the upper die 105. In this process, the solder bumps 104 will melt to establish solder joints to leadframe 205 in a defined temperature reflow profile that is lower than the temperature used during the attachment of die 107 so the solder bumps 108 will not re-melt. In some embodiments, the melting point of bump 108 for die 107 is about 310° C. and the melting point of bump 104 for die 105 is about 250° C. In this process, the solder bumps 104 become attached to the leadframe 205 to connect the upper die (and therefore the rest of the structure) to this leadframe.

At this stage, if the device is to contain a molding or encapsulation material, it is then provided. As known in the art, the molding material (i.e., epoxy) is coated onto the die assembly and lead frames and then cured. Excess molding material is then removed so that the resulting device is similar to that depicted in FIG. 23.

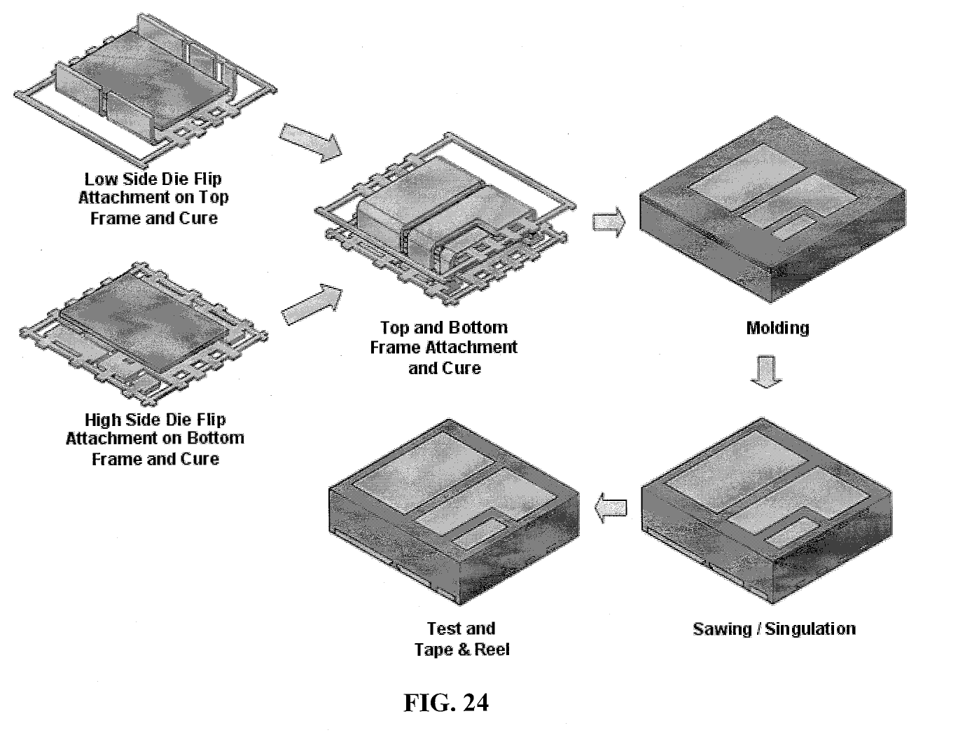

In other embodiments, the method depicted in FIG. 24 can be used to form the semiconductor packages 200. This method is similar to that method depicted in FIG. 23, except that each of the dies is first attached to its respective lead frame. Then the two dies are attached to each other.

Once these processes are performed, the devices are singulated as known in the art. Then, the singulated semiconductor packages may be electrically tested. After electrical testing, the molding material in the semiconductor packages may be laser marked. Finally, the devices may be taped and reeled as known in the art.

The devices in these embodiments have several advantages. The first advantage comprises the size of the land pattern and the overall package. The devices described above have a compact dual die configuration by stacking the dies in a back to back configuration. Other devices with a dual die configuration usually fold, rather than stack, the dies together. With the back to back stacked-die configuration, the devices use a smaller land pattern area and therefore have a smaller package size.

Another advantage of the devices described above relates to the flexibility of the end uses of the devices. The devices have a stacked back-to-back die configuration where the drain of lower die 107 can be connected to the source of upper die 105 as shown in FIG. 28. The connection between the upper die 105 and the lower die 107 provides the semiconductor package 200 with a half bridge configuration. This configuration enables an end user not to need extra wiring layout for a half bridge application, such as in scan driver block and inverter blocks.

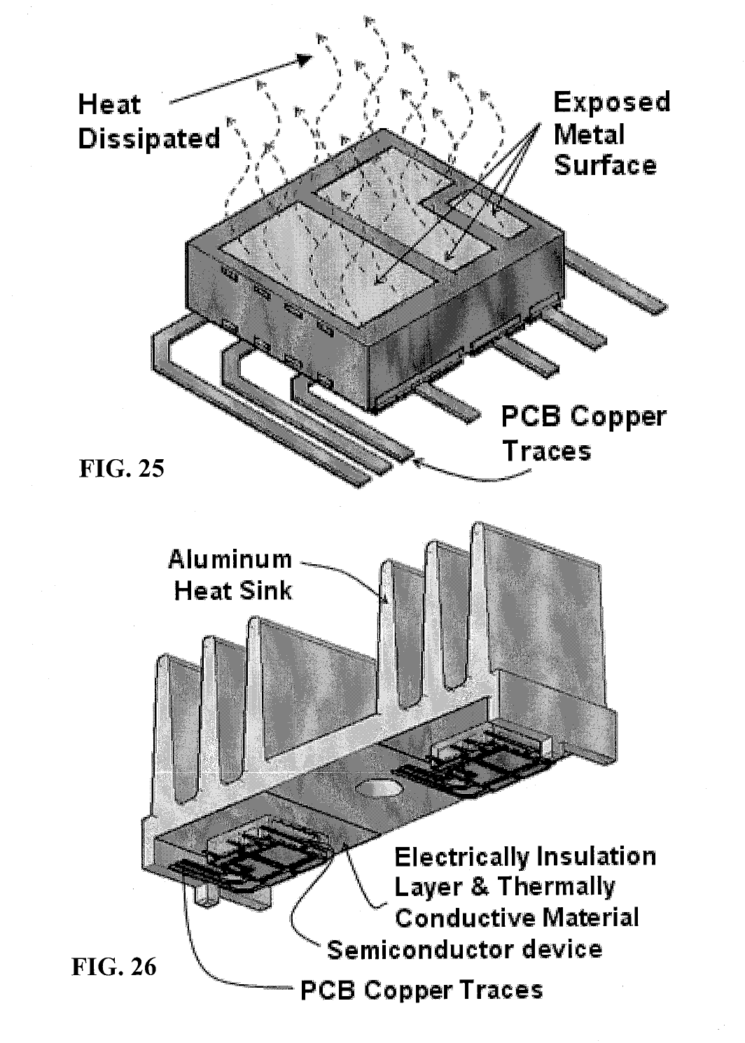

Another advantage involves the heat dissipation characteristics of the semiconductor packages 200. As shown in FIG. 25, these devices contain an exposed upper metal surface which is connected to the MOSFET of the upper die (which is in turn connected to the back side of the MOSFET in the lower die). Such a configuration allows heat to quickly be conducted upwards as the heat dissipates to the environment surrounding the package 200. As well, such a configuration also allows alternatives in optimizing heat dissipation by allowing an external heat sink to be used, as shown in FIG. 26.

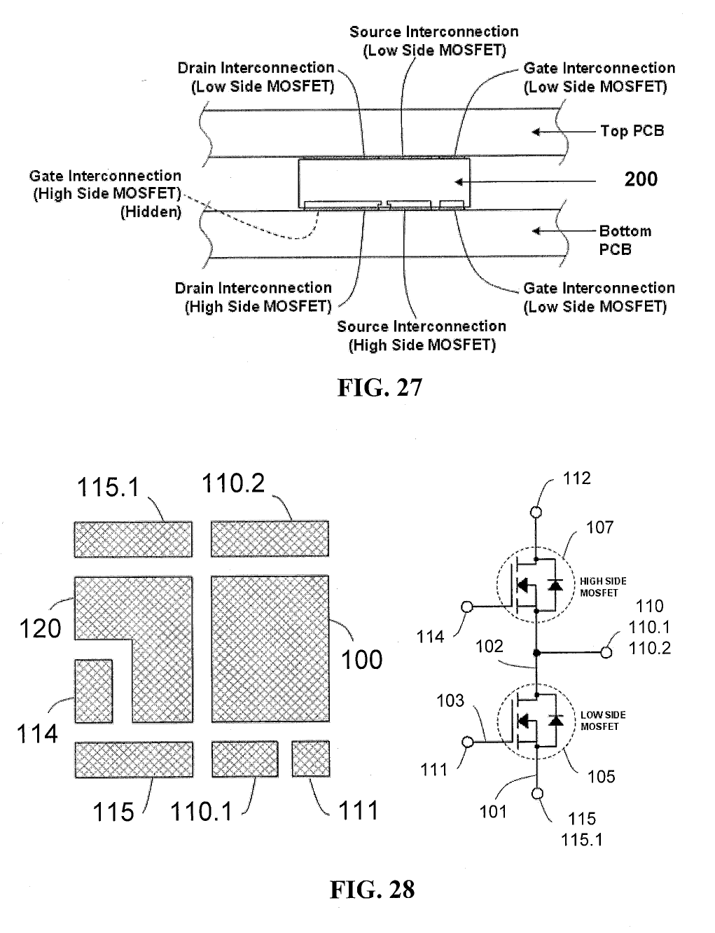

Yet another advantage of these devices relates to the interconnection flexibility. The exposed metal of the leadframe 205 on the upper surface of the semiconductor package 200 can serve as an alternate interconnection, in addition to the terminals of the leadframe 210 at the bottom of the package. This configuration thereby allows a flexible mounting interconnection that could be used, for example as shown in FIG. 27, in a dual PCB connection.

Another advantage of the devices described above relate to the location of the bumps. As described above, the gate, source and drain bumps for each of the upper and lower dies are located on one side of the die. Such configuration allows simplicity for all of the electrical connections towards the gate, source and drain. And unlike conventional dies, the functional drain terminal is provided at the back side of the die.

Having described the preferred aspects of the devices and associated methods, it is understood that the appended claims are not to be limited by particular details set forth in the above description, as many apparent variations thereof are possible without departing from the spirit or scope thereof.

1. A semiconductor device, comprising:
a leadframe containing multiple terminals for connection to an external device;
a first die attached to the leadframe through an array of first solder bumps located on an active surface of the first die; and
a second die attached to the first die so that an inactive surface of the two dies are proximate each other, leaving an active surface of the second die available to be connected to the external device through an array of second solder bumps.

2. The device of claim 1, wherein the external device comprises a printed circuit board.

3. The device of claim 1, wherein the first and second die are electrically isolated from each other.

4. The device of claim 3, wherein the isolation is performed by an insulating layer located between the inactive surfaces of the first and second dies, the insulating layer also adhesively attaching the first and second dies together.

5. The device of claim 1, wherein the active surface of the first and second dies contain a MOSFET with a source, gate, and drain.

6. The device of claim 1, further comprising a support structure attached to the leadframe on a surface opposite the first die.

7. The device of claim 1, wherein the bottom surface of the terminals of the leadframe is substantially planar with the bottom of the second solder bumps.

8. The device of claim 1, further comprising a molding material that encapsulates the active surface of the first die, the first solder bumps, and the surface of the leadframe proximate the first solder balls.

9. A semiconductor device, comprising:
a first leadframe containing multiple terminals;
a first die attached to the leadframe through an array of first solder bumps located on an active surface of the first die; and
a second die attached to the first die so that an inactive surface of the two dies are proximate each other, the second die containing an array of second solder bumps; and
a second leadframe attached to the second die through the second solder bumps; wherein the terminals of the first leadframe are electrically connected to the second leadframe.

10. The device of claim 9, wherein the first and second die are electrically isolated from each other.

11. The device of claim 10, wherein the isolation is performed by an insulating layer located between the inactive surfaces of the first and second dies, the insulating layer also adhesively attaching the first and second dies together.

12. The device of claim 9, wherein the active surface of the first and second dies contain a MOSFET with a source, gate, and drain.

13. The device of claim 9, further comprising a molding material that substantially encapsulates the device except for a portion of the upper surface of the first leadframe and a portion of the bottom surface of the second leadframe.

14. The device of claim 13, wherein the exposed surface of the first leadframe increases the dissipation of heat away from the device.

15. An electronic apparatus containing a semiconductor device containing:
a leadframe containing multiple terminals for connection to an external device;
a first die attached to the leadframe through an array of first solder bumps located on an active surface of the first die; and
a second die attached to the first die so that an inactive surface of the two dies are proximate each other, leaving an active surface of the second die available to be connected to the external device through an array of second solder bumps.

16. A method for making a making a semiconductor device, comprising:
providing a leadframe containing multiple terminals;
attaching a first die to the leadframe through an array of first solder bumps located on an active surface of the first die;
attaching a second die to the first die so that an inactive surface of the two dies are proximate each other, wherein the second die contains an array of second solder bumps; and
connecting the multiple terminals and the array of second solder bumps to an external device.

17. The method of claim 16, wherein the external device comprises a printed circuit board.

18. The method of claim 16, further comprising attaching the first and second die to each other before connecting the first die to the leadframe.

19. The method of claim 16, further comprising attaching the first and second die using an insulating layer that also adhesively attaches the first and second dies together.

20. The method of claim 16, wherein the active surface of the first and second dies contain a MOSFET with a source, gate, and drain.

21. A method for making a semiconductor device, comprising:
providing a first leadframe containing multiple terminals;
attaching a first die attached to the leadframe through an array of first solder bumps located on an active surface of the first die;
attaching a second die to the first die so that an inactive surface of the two dies are proximate each other, wherein the second die contains an array of second solder bumps; and
attaching a second leadframe attached to the second die through the second solder bumps so that the terminals of the first leadframe are electrically connected to the second leadframe.

22. The method of claim 21, further comprising attaching the first die to the first leadframe the second die to the second leadframe before connecting the first and second dies to each other.

23. The method of claim 21, further comprising attaching the first and second die using an insulating layer that also adhesively attaches the first and second dies together.

24. The method of claim 21, wherein the active surface of the first and second dies contain a MOSFET with a source, gate, and drain.

25. The method of claim 21, further comprising providing a molding material that substantially encapsulates the device except for a portion of the upper surface of the first leadframe and a portion of the bottom surface of the second leadframe.
